(19) United States
(12) Patent Application Publication
(10) Pub. No.: US 2018/0246368 A1
(43) Pub. Date: Aug. 30, 2018

(54) BLACK MATRIX, METHOD FOR MANUFACTURING THE SAME AND LIQUID PANEL HAVING THE SAME

(71) Applicant: Shenzhen China Star Optoelectronics Technology Co., Ltd., Shenzhen City (CN)

(72) Inventors: Chengzhong Yu, Shenzhen City (CN); Yahui Chen, Shenzhen City (CN); Hsiaohsien Chen, Shenzhen City (CN); Yungjui Lee, Shenzhen City (CN)

(21) Appl. No.: 14/764,986

(22) PCT Filed: May 13, 2015
(86) PCT No.: PCT/CN2015/078867

§ 371 Date: Apr. 15, 2018

(30) Foreign Application Priority Data
Mar. 23, 2015 (CN) 201510128299.3

(51) Int. Cl. G02F 1/1335; G02F 1/1362; C09J 131/08; G03F 7/085

(52) U.S. Cl. CPC G02F 1/133512; G02F 1/133514; C08L 25/04; C09J 131/08; G03F 7/085; G02F 1/1362

(57) ABSTRACT

The disclosure provides a black matrix, a method for manufacturing the same and a liquid panel having the same. The black matrix is manufactured by the following steps. A mixture of resin compositions is coated on a substrate. After being dried, the black matrix is patterned by lithography. The mixture of resin compositions includes an adhesive resin, a photoinitiator, a small molecule monomer, a solvent, a light shielding material, an azo compound and an additive. According to the disclosure, the light shielding ability density of the black matrix is improved and the optical density of the black matrix of is increased by adding the azo compound having the property of polarization. Also, the usage of light shielding material in the black matrix is decreased and resistance of the black matrix is increased.

### TECHNICAL FIELD

The disclosure is related to the field of display technology, and more particularly to a black matrix, method for manufacturing the same and liquid panel having the same.

### RELATED ART

Liquid crystal displays (LCD) are widely used because of their advantages, such as thin structures, low power consumption and they can function without radiation. For example, liquid crystal displays are used in LCD TVs, mobile phones, personal digital assistants (PDA), digital cameras, screens of computers or notebooks.

In general, a liquid crystal display comprises a shell, a liquid crystal display panel disposed inside the shell and a backlight module disposed inside the shell. Wherein, the liquid crystal display panel comprises a thin film transistor array substrate (TFT array substrate), a color filler substrate (CF substrate) and a liquid crystal layer disposed between the TFT array substrate and the CF substrate. The rotation of liquid crystal molecules inside the liquid crystal layer is controlled by applying a drive voltage between the two glass substrates, such that the light beam from the backlight module is refracted for generating images.

At present, in mainstream liquid crystal panels, a black matrix (BM) is disposed at a lateral side of the CF substrate for preventing the leakage of light of each pixel. At the beginning, metal thin films of chromium material are used as the black matrix. However, since the process is complicated, the cost is high, and the process is environmental unfriendly, so that they are gradually replaced by resin black matrix. Resin black matrix (RBM) is that light shielding material, such as carbon black, is dispersed in the resin, mixed with other resins, photoinitiators, monomers, solvents, and they are coated on a CF substrate. After drying, the black matrix is formed by pattering through lithography. Optical density (OD) is used for evaluating the ability of shielding light. Accompanied with the development of color filter sheets, it is more and more important to improve the optical density of the resin black matrix. At present, the following methods are used to increase the optical density of the matrix:

I. Increase the thickness of the film of photoresist of the black matrix. This method would meet the problem that the surface gradient of the color pixels (R, G, B), which are coated on the black matrix, become greater, so that the filters are less flat and the orientation of the liquid crystals become random.

II. Increase the content of light shielding material, such as carbon, while remaining the thickness of the film. This method would meet the problem that the ratio of resin in the resin type black matrix being decreased, such that the adhesion of the substrate is lowered. In addition, carbon black would absorb ultraviolet during the exposure process, so that the photoresist at the bottom layer cannot be solidified and would be stripped because it is lack of exposure.

III. Decrease the diameter of carbon black for increasing the ability of light shielding. This method would meet the problem that the particles are agglomerated. In addition, since carbon black is electrically conductive, the resistance (Rs) of the black matrix would be lowered when the photoresist system has more carbon black.

### SUMMARY

The disclosure provides a black matrix, which has a greater optical density, and the usage of light shielding material is smaller as well as the black matrix has a greater resistance.

The disclosure also provides a method for manufacturing a black matrix, such that the optical density of the black matrix is increased, the usage of light shielding material is smaller, the resistance of the black matrix is increased as well as the stability of the filming process of the black matrix is improved.

The disclosure also provides a liquid crystal panel, such that the matrix on the CF substrate has both the properties of polarization and absorption, such that the light shielding ability is improved, the optical density is increased, the usage of light shielding material in the black matrix is smaller, and greater resistance is increased.

In order to achieve the above purposes, the disclosure provides a black matrix, manufactured by the steps of coating a mixture of resin compositions on a substrate, drying the mixture, and patterning by lithography, wherein the mixture of resin compositions comprises an adhesive resin, a photoinitiator, a small molecule monomer, a solvent, a light shielding material, an azo compound and an additive, and the azo compound has the property of polarization.

The azo compound has the formula of

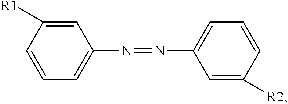

wherein R1 is amino, hydroxyl, alkoxy, ester, aminoacyl, amine-aldehyde, phenyl or alkyl, and R2 is acyl, aldehyde, carboxyl, amide, sulfonic acid, nitrile, nitro, haloform or quaternary amino.

The light shielding material is a black inorganic pigment or a black organic pigment, the adhesive resin is 2-(methyl) acryloyloxyethyl phthalate, the small molecule monomer is styrene, acrylate or methacrylate, the photoinitiator is ethanone or 1-[9-ethyl-6(2-methylbenzoyl)-9H-substituent carbazol-3-yl]-1-(oxo-acetyloxime), and the solvent is propylene glycol monomethyl ether acetate, cyclohexanone, 3-methoxy butyl acetate or 2-(2-butoxyethoxy)-Ethanol acetate.

The black inorganic pigment is carbon black, chromium oxide, iron oxide, titanium oxide or graphite, and the black organic pigment is perylene black, cyanine black or aniline black.

The mixture of resin compositions has the following composition: 5˜10 wt % of adhesive resin, 0˜1 wt % of photoinitiator, 0˜1 wt % of small molecule monomer, 70˜80 wt % of solvent, 5˜10 wt % of light shielding material, 1˜5 wt % of azo compound and 0˜0.5 wt % of additive.

The disclosure further provides a method for manufacturing a black matrix, comprising:

Step 1, 5˜10 wt % of adhesive resin is weighed, 0˜1 wt % of photoinitiator is weighed, 0˜1 wt % of small molecule monomer is weighed, 70˜80 wt % of solvent is weighed, 5˜10 wt % of light shielding material is weighed, 1˜5 wt % of azo compound is weighed and 0˜0.5 wt % of additive is weighed based on the total weight of a manufactured mixture of resin compositions, then the weighed components are mixed for manufacturing the mixture of resin compositions, wherein the azo compound has the property of polarization; and

Step 2, the mixture of resin compositions is coated on a substrate and a black matrix having the property of polarization is formed by soft baking, exposing, developing, and hard baking.

In step 1, the azo compound has the formula of

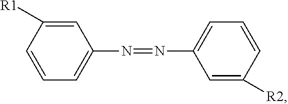

wherein R1 is amino, hydroxyl, alkoxy, ester, aminoacyl, amine-aldehyde, phenyl or alkyl, and R2 is acyl, aldehyde, carboxyl, amide, sulfonic acid, nitrile, nitro, haloform or quaternary amino.

In step 1, the light shielding material is a black inorganic pigment or a black organic pigment, the adhesive resin is 2-(methyl) acryloyloxyethyl phthalate, the small molecule monomer is styrene, acrylate or methacrylate, the photoinitiator is ethanone or 1-[9-ethyl-6(2-methylbenzoyl)-9H-substituent carbazol-3-yl]-1-(oxo-acetyloxime), and the solvent is propylene glycol monomethyl ether acetate, cyclohexanone, 3-methoxy butyl acetate or 2-(2-butoxyethoxy)-Ethanol acetate.

The black inorganic pigment is carbon black, chromium oxide, iron oxide, titanium oxide or graphite, and the black organic pigment is perylene black, cyanine black or aniline black.

The disclosure further provides a liquid crystal panel, comprising a CF substrate, a TFT substrate disposed opposite to the CF substrate and a liquid crystal layer filled between the CF substrate and the TFT substrate, wherein a black matrix according to any one of the above black matrix and a color photoresist are disposed on the CF substrate.

The disclosure has the following advantages: according to the disclosure, the black matrix includes azo compound having the property of polarization, the black matrix has a better ability of light shielding, the black matrix has a higher optical density, the usage of light shielding material in the black matrix is smaller, and the black matrix has a greater resistance. According to the disclosure, the method for manufacturing a black matrix incorporates azo compound having the property of polarization in the black matrix, such that the black matrix has a better ability of light shielding, the black matrix has a higher optical density. In addition, since the azo compound is incorporated, the usage of light shielding material in the black matrix is smaller, and the resistance of the black matrix is increased. Meanwhile, it is easier for ultraviolet to achieve the bottom of the film during the exposure process, such that there are fewer problems in engineering as well as the stability of the process is improved. According to the liquid crystal panel of the disclosure, the black matrix on the CF substrate includes azo compound having the property of polarization, such that it includes both the properties of polarization and absorption. The black matrix absorbs and shields the polarizing light, which is polarized after passing through the bottom polarizing plate and the liquid crystal, by the light shielding material. In addition, the black matrix polarizes the light. Thus, when the light is transmitted to the black matrix, the bottom polarizing plate and the black matrix form a polarizing system, and the ability of shielding light is further improved, and the optical density of the black matrix is increased. Meanwhile, since the azo compound is incorporated, the usage of light shielding material in the black matrix is decreased and the resistance of the black matrix is increased.

In order to more clearly illustrate the features and technical solutions of the disclosure, the accompanying descriptions and drawings are described as blow. It is apparently that the drawings below are merely some embodiments of the disclosure, which do not limit the scope of the disclosure.

### BRIEF DESCRIPTION OF THE DRAWINGS

In order to more clearly illustrate the embodiments of the disclosure, the accompanying drawings for illustrating the technical solutions and the technical solutions of the disclosure are briefly described as below.

In drawings,

FIG. 1 is a schematic view of the molecular orbital of the azo compound in the black matrix of the disclosure;

FIG. 2 is a diagram of the resistance and the content of carbon black according to the present black matrix;

FIG. 3 is flow chart of the method for manufacturing a black matrix according to the disclosure;

FIG. 4 is a sectional view of the liquid crystal panel according to the disclosure;

FIG. 5 is a diagram of incident light according to the present liquid crystal panel;

FIG. 6 is a diagram of incident light according to the liquid crystal panel of the disclosure; and

FIG. 7 is a diagram of the optical density and the content of carbon black according to the black matrix of the disclosure and present black matrix.

### DETAILED DESCRIPTION

The following description with reference to the accompanying drawings is provided to clearly and completely explain the exemplary embodiments of the disclosure. It is apparent that the following embodiments are merely some embodiments of the disclosure rather than all embodiments of the disclosure. According to the embodiments in the disclosure, all the other embodiments attainable by those skilled in the art without creative endeavor belong to the protection scope of the disclosure.

First of all, the disclosure provides a black matrix, manufactured by the steps of coating a mixture of resin compositions on a substrate, drying the mixture, and patterning by lithography, wherein the mixture of resin compositions comprises an adhesive resin (polymer), a photoinitiator, a small molecule monomer (monomer), a solvent, a light shielding material, an azo compound and an additive, and the azo compound has the property of polarization. The adhesive resin can form a layer of film and support the cross linking reaction. The photoinitiator can rapidly form a radical when illuminated by light. The small molecule monomer can polymerize. The solvent can adjust the property of coating. The light shielding material can shield light. The azo compound has the property of polarization and can be uniformly dispersed in the system.

Specifically, the azo compound of the disclosure is an aromatic azo compound, which has the formula of

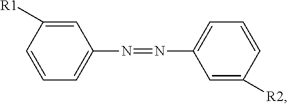

wherein R1 is an electron donating group, such as amino, hydroxyl, alkoxy, ester, aminoacyl, amine-aldehyde, phenyl, alkyl and so forth, and R2 is an electron withdrawing group, such as acyl, aldehyde, carboxyl, amide, sulfonic acid, nitrile, nitro, haloform, quaternary amino and so forth.

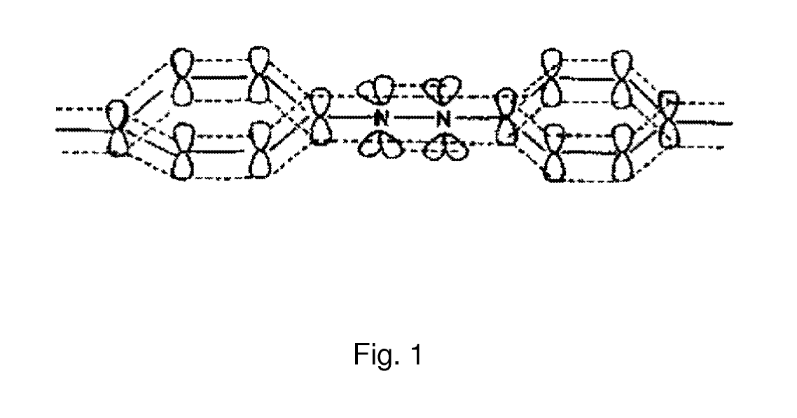

Referring FIG. 1, FIG. 1 is a schematic view of the molecular orbital of the azo compound in the black matrix of the disclosure. The two aryls are connected by N═N in the azo compound, such that a resonance structure is formed. Thus, the bonding in the molecule is rigid and the molecule has a linear and co-planar structure, so that the azo compound has the property of polarization.

Specifically, in some embodiments, light shielding material is a black inorganic pigment, such as carbon black, chromium oxide, iron oxide, titanium oxide, graphite and so forth; in some other embodiments, the light shielding material is a black organic pigment, which has better thermal resistance, light resistance and solvent resistance, such as perylene black, cyanine black, aniline black and so forth.

The adhesive resin is an alkali-soluble resin, such as 2-(methyl) acryloyloxyethyl phthalate and so forth.

The small molecule monomer has an unsaturated double bond, such as styrene, acrylate, methacrylate and so forth.

The photoinitiator is ethanone or 1-[9-ethyl-6(2-methylbenzoyl)-9H-substituent carbazol-3-yl]-1-(oxo-acetyloxime) (CGI-2424, Ciba Specialty Chemicals).

The solvent is propylene glycol monomethyl ether acetate (PGMEA), cyclohexanone, 3-methoxy butyl acetate, 2-(2-butoxyethoxy)-Ethanol acetate and so forth.

Specially, the mixture of resin compositions has the following composition: 5˜10 wt % of adhesive resin, 0˜1 wt % of photoinitiator, 0˜1 wt % of small molecule monomer, 70˜80 wt % of solvent, 5˜10 wt % of light shielding material, 1˜5 wt % of azo compound and 0˜0.5 wt % of additive.

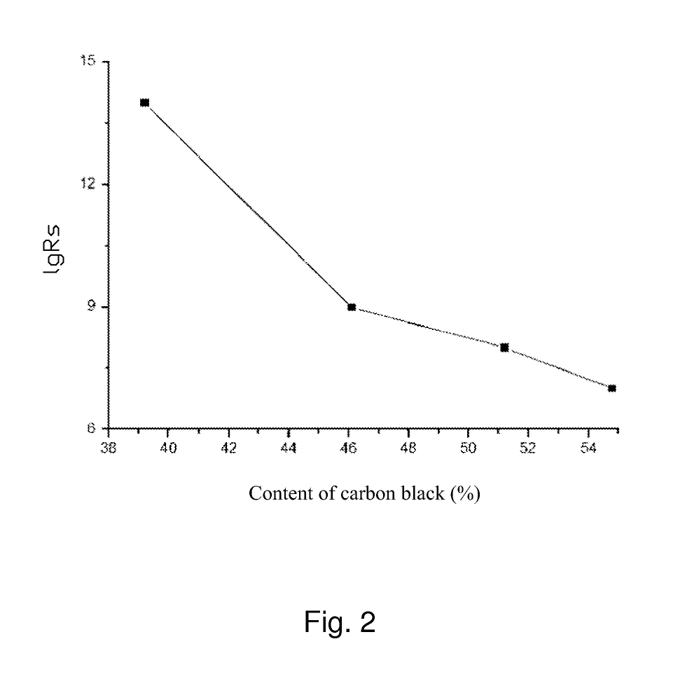

Referring FIG. 2, FIG. 2 is a diagram of the resistance (Rs) and the content of carbon black according to the present black matrix.

Referring Table 1, Table 1 refers to the relationship between the optical density (OD)/resistance (Rs) and the content of carbon black according to the present black matrix.

TABLE 1
The relationship between the optical density (OD)/resistance
(Rs) and the content of carbon black.

| Content of carbon black % | OD value/um | Rs (280° C./30 mins) |
|---|---|---|
| 39.2 | 2.95 | 10¹⁴ |
| 46.1 | 3.42 | 10⁹ |
| 51.2 | 3.81 | 10⁸ |
| 54.8 | 4.02 | 10⁷ |

According to FIG. 2 and Table 1, when carbon black is used as the light shielding material of the black matrix, the optical density of the black matrix in the liquid crystal panel is determined by the content of carbon black. Under the same conditions, when the content of carbon black in the black matrix is greater, the corresponding optical density is greater. However, since carbon black is electrically conductive, when the content of carbon black in the black matrix is greater, the resistance of the black matrix is smaller. In the disclosure, since azo compound is incorporated, the usage of the light shielding material, such as carbon black, can be reduced while remaining the same optical density, so that the resistance of the black matrix is increased.

According to the disclosure, the black matrix has azo compound having the property of polarization, such that the light shielding ability of the black matrix is improved and the optical density of the black matrix is increased. Also, the usage of light shielding material in the black matrix is decreased and resistance of the black matrix is increased.

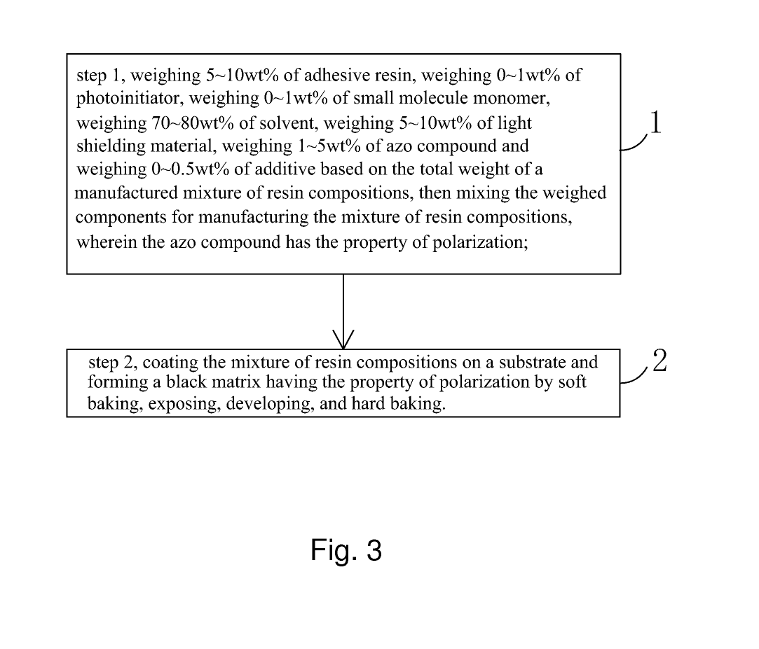

Referring FIG. 3, the disclosure further provides a method for manufacturing a black matrix, comprising:

Step 1, 5˜10 wt % of adhesive resin is weighed, 0˜1 wt % of photoinitiator is weighed, 0˜1 wt % of small molecule monomer is weighed, 70˜80 wt % of solvent is weighed, 5˜10 wt % of light shielding material is weighed, 1˜5 wt % of azo compound is weighed and 0˜0.5 wt % of additive is weighed based on the total weight of a manufactured mixture of resin compositions, then the weighed components are mixed for manufacturing the mixture of resin compositions, wherein the azo compound has the property of polarization.

Specifically, in some embodiments, light shielding material is a black inorganic pigment, such as carbon black, chromium oxide, iron oxide, titanium oxide, graphite and so forth; in some other embodiments, the light shielding material is a black organic pigment, which has better thermal resistance, light resistance and solvent resistance, such as perylene black, cyanine black, aniline black and so forth.

The adhesive resin is an alkali-soluble resin, such as 2-(methyl) acryloyloxyethyl phthalate and so forth.

The small molecule monomer has an unsaturated double bond, such as styrene, acrylate, methacrylate and so forth.

The photoinitiator is ethanone or 1-[9-ethyl-6(2-methylbenzoyl)-9H-substituent carbazol-3-yl]-1-(oxo-acetyloxime) (CGI-2424, Ciba Specialty Chemicals).

The solvent is propylene glycol monomethyl ether acetate (PGMEA), cyclohexanone, 3-methoxy butyl acetate, 2-(2-butoxyethoxy)-Ethanol acetate and so forth.

The azo compound of the disclosure has the formula of

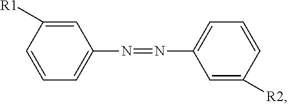

wherein R1 is an electron donating group, such as amino, hydroxyl, alkoxy, ester, aminoacyl, amine-aldehyde, phenyl, alkyl and so forth, and R2 is an electron withdrawing group, such as acyl, aldehyde, carboxyl, amide, sulfonic acid, nitrile, nitro, haloform, quaternary amino and so forth.

Step 2, the mixture of resin compositions is coated on a substrate and a black matrix having the property of polarization is formed by soft baking, exposing, developing, and hard baking.

It should be noticed that a directional stretch process is not performed to the black matrix during the hard baking process, such that the selectivity of polarized light of the manufactured black matrix is relatively random.

According to the above described method for manufacturing a black matrix, the method incorporates azo compound having the property of polarization in the black matrix, such that the black matrix has a better ability of light shielding, the black matrix has a higher optical density. In addition, since the azo compound is incorporated, the usage of light shielding material in the black matrix is smaller, and the resistance of the black matrix is increased. Meanwhile, it is easier for ultraviolet to achieve the bottom of the film during the exposure process of the yellow light manufacturing process of the black matrix, such that there are fewer problems in engineering as well as the stability of the process is improved.

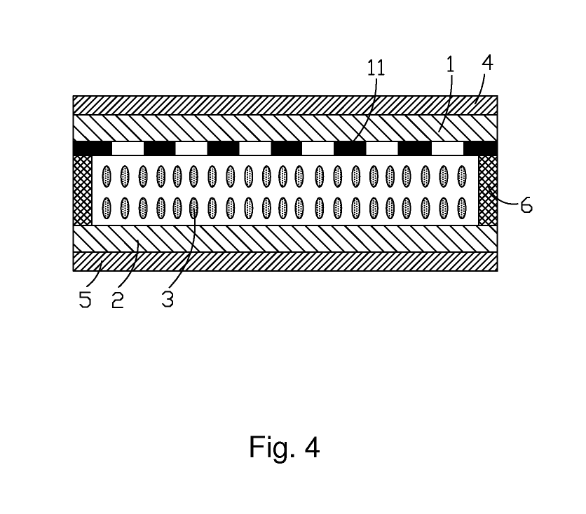

Referring FIG. 4, the disclosure further provides a liquid crystal panel, comprising a CF substrate 1, a TFT substrate 2 disposed opposite to the CF substrate 1, a liquid crystal layer 3 filled between the CF substrate 1 and the TFT substrate 2, a top polarizing plate 4 disposed on the top surface of the CF substrate 1, a bottom polarizing plate 5 disposed at the bottom surface of the TFT substrate 2, and a plastic frame 6 bonded to the CF substrate 1 and the TFT substrate 2. A black matrix 11 and a color photoresist are disposed on the CF substrate 1. The black matrix 11 is manufactured by the steps of coating a mixture of resin compositions on a substrate, drying the mixture, and patterning by lithography. The mixture of resin compositions comprises an adhesive resin, a photoinitiator, a small molecule monomer, a solvent, a light shielding material, an azo compound and an additive. The azo compound has the property of polarization.

Specifically, in some embodiments, light shielding material is a black inorganic pigment, such as carbon black, chromium oxide, iron oxide, titanium oxide, graphite and so forth; in some other embodiments, the light shielding material is a black organic pigment, which has better thermal resistance, light resistance and solvent resistance, such as perylene black, cyanine black, aniline black and so forth.

The adhesive resin is an alkali-soluble resin, such as 2-(methyl) acryloyloxyethyl phthalate and so forth.

The small molecule monomer has an unsaturated double bond, such as styrene, acrylate, methacrylate and so forth.

The photoinitiator is ethanone or 1-[9-ethyl-6(2-methylbenzoyl)-9H-substituent carbazol-3-yl]-1-(oxo-acetyloxime) (CGI-2424, Ciba Specialty Chemicals).

The solvent is propylene glycol monomethyl ether acetate (PGMEA), cyclohexanone, 3-methoxy butyl acetate, 2-(2-butoxyethoxy)-Ethanol acetate and so forth.

The azo compound of the disclosure has the formula of

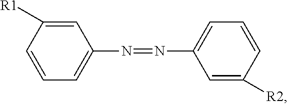

wherein R1 is an electron donating group, such as amino, hydroxyl, alkoxy, ester, aminoacyl, amine-aldehyde, phenyl, alkyl and so forth, and R2 is an electron withdrawing group, such as acyl, aldehyde, carboxyl, amide, sulfonic acid, nitrile, nitro, haloform, quaternary amino and so forth.

Specially, the mixture of resin compositions has the following composition: 5˜10 wt % of adhesive resin, 0˜1 wt % of photoinitiator, 0˜1 wt % of small molecule monomer, 70˜80 wt % of solvent, 5˜10 wt % of light shielding material, 1˜5 wt % of azo compound and 0˜0.5 wt % of additive.

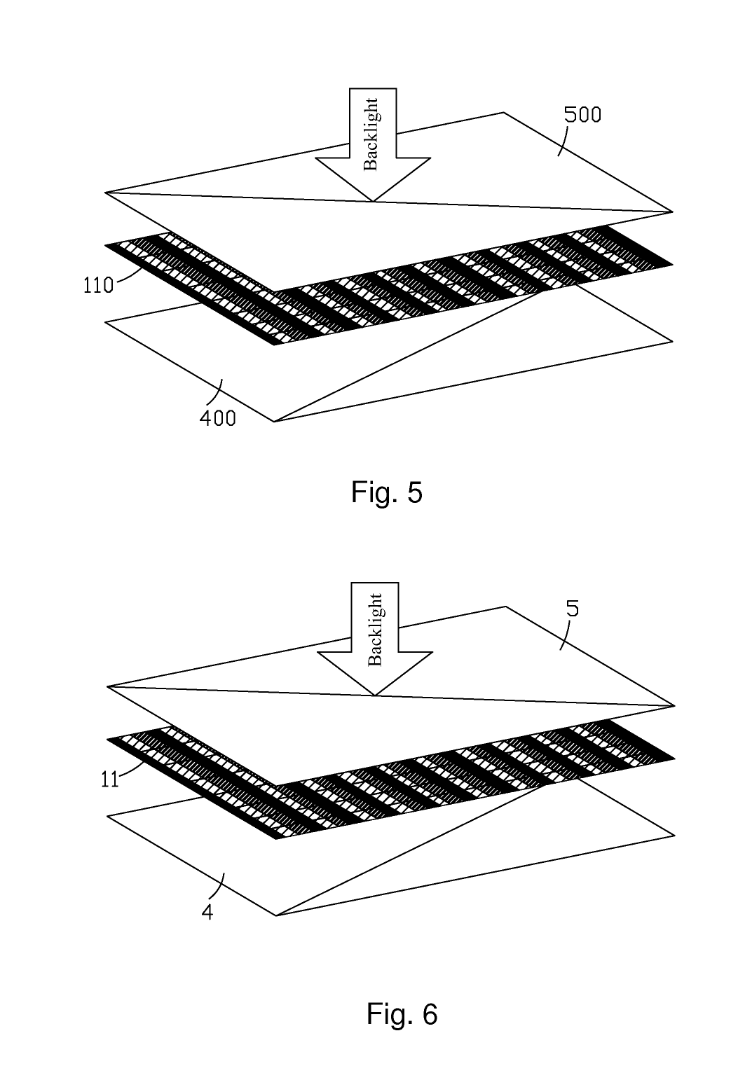

Referring FIG. 5, FIG. 5 is a diagram of incident light according to the present liquid crystal panel. The black matrix 110 of the present liquid crystal panel includes an adhesive resin, a photoinitiator, a small molecule monomer, a solvent, a carbon black and an additive. The black matrix of the present liquid crystal panel does not include an azo compound, such that the black matrix 110 only has the ability of shielding light. When a backlight enters the bottom polarizing plate 500, the black matrix 110 absorbs and shields the polarizing light, which is polarized after passing through the bottom polarizing plate 500 and the liquid crystal, by the carbon black. Finally, the light emits from the top polarizing plate 400. Since the intensity of light passing through the color filter substrate is merely determined by the content of carbon black, such that the ability of shielding light is worse, and the transmittance is relatively higher.

Referring FIG. 6, FIG. 6 is a diagram of incident light according to the liquid crystal panel of the disclosure. The azo compound having the property of polarization is added into the black matrix 11 of the liquid crystal panel of the disclosure. When a backlight enters the bottom polarizing plate 5, the black matrix 11 absorbs, shields and the polarizing light, which is polarized after passing through the bottom polarizing plate 5 and the liquid crystal, by the carbon black. Thus, when the light is transmitted to the black matrix 11, the bottom polarizing plate 5 and the black matrix 11 form a polarizing system, and finally the light emits from the top polarizing plate 4. The black matrix 11 has the properties of polarization and absorption, such that the ability of shielding light is further improved, the transmittance is decreased (the transmittance can be decreased to be a lowest value of 3.5%), so that the optical density of the black matrix 11 is increased. Meanwhile, since the azo compound is incorporated, the usage of light shielding material in the black matrix is decreased and the resistance of the black matrix 11 is increased.

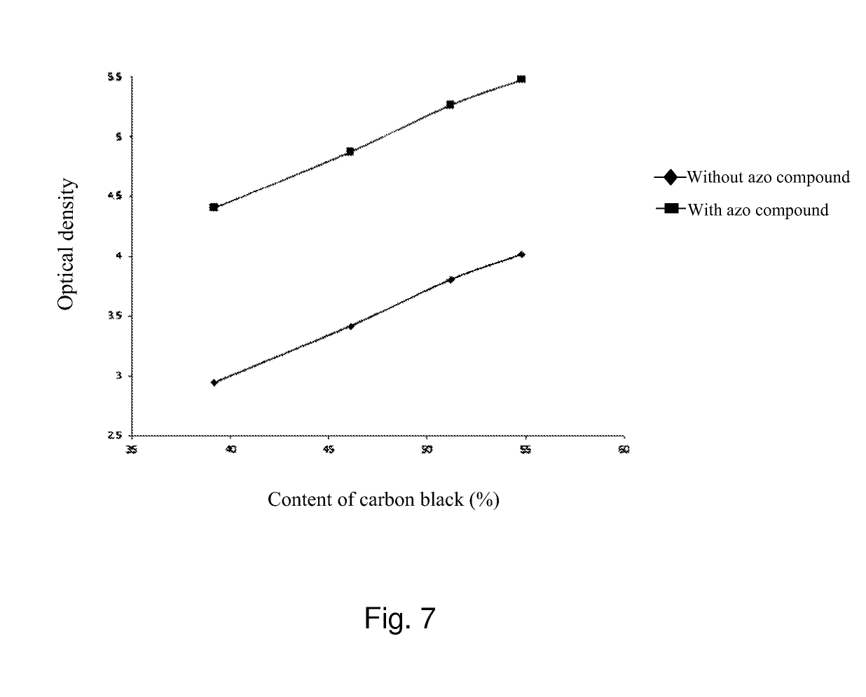

Referring FIG. 7, FIG. 7 is a diagram of the optical density and the content of carbon black according to the black matrix of the disclosure and present black matrix. The black matrix of the disclosure includes azo compound and the black matrix of present black matrix does not include azo compound. According to FIG. 7, when having the same content of carbon black, the black matrix of the disclosure has a higher optical density and a better light shielding ability than the black matrix of present black matrix. In addition, when having the same optical density, the black matrix of the disclosure has lower content of carbon black than the black matrix of present black matrix, such that the black matrix of the disclosure has a higher resistance.

According to the liquid crystal panel of the disclosure, the black matrix on the CF substrate includes azo compound having the property of polarization, such that it includes both the properties of polarization and absorption. The black matrix absorbs and shields the polarizing light, which is polarized after passing through the bottom polarizing plate and the liquid crystal, by the light shielding material. In addition, the black matrix polarizes the light. Thus, when the light is transmitted to the black matrix, the bottom polarizing plate and the black matrix form a polarizing system, and the ability of shielding light is further improved, and the optical density of the black matrix is increased. Meanwhile, since the azo compound is incorporated, the usage of light shielding material in the black matrix is decreased and the resistance of the black matrix is increased.

As described above, the black matrix of the disclosure includes azo compound having the property of polarization, the black matrix has a better ability of light shielding, the black matrix has a higher optical density, the usage of light shielding material in the black matrix is smaller, and the black matrix has a greater resistance. The method for manufacturing a black matrix of the disclosure incorporates azo compound having the property of polarization in the black matrix, such that the black matrix has a better ability of light shielding, the black matrix has a higher optical density. In addition, since the azo compound is incorporated, the usage of light shielding material in the black matrix is smaller, and the resistance of the black matrix is increased. Meanwhile, it is easier for ultraviolet to achieve the bottom of the film during the exposure process, such that there are fewer problems in engineering as well as the stability of the process is improved. According to the liquid crystal panel of the disclosure, the black matrix on the CF substrate includes azo compound having the property of polarization, such that it includes both the properties of polarization and absorption. The black matrix absorbs and shields the polarizing light, which is polarized after passing through the bottom polarizing plate and the liquid crystal, by the light shielding material. In addition, the black matrix polarizes the light. Thus, when the light is transmitted to the black matrix, the bottom polarizing plate and the black matrix form a polarizing system, and the ability of shielding light is further improved, and the optical density of the black matrix is increased. Meanwhile, since the azo compound is incorporated, the usage of light shielding material in the black matrix is decreased and the resistance of the black matrix is increased.

Note that the specifications relating to the above embodiments should be construed as exemplary rather than as limitative of the present disclosure. The equivalent variations and modifications on the structures or the process by reference to the specification and the drawings of the disclosure, or application to the other relevant technology fields directly or indirectly should be construed similarly as falling within the protection scope of the disclosure.

1. A black matrix, manufactured by the steps of coating a mixture of resin compositions on a substrate, drying the mixture, and patterning by lithography, wherein the mixture of resin compositions comprises an adhesive resin, a photoinitiator, a small molecule monomer, a solvent, a light shielding material, an azo compound and an additive, and the azo compound has the property of polarization.

2. The black matrix according to claim 1, wherein the azo compound has the formula of 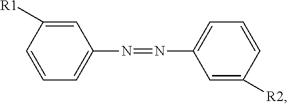
wherein R1 is amino, hydroxyl, alkoxy, ester, aminoacyl, amine-aldehyde, phenyl or alkyl, and R2 is acyl, aldehyde, carboxyl, amide, sulfonic acid, nitrile, nitro, haloform or quaternary amino.

3. The black matrix according to claim 1, wherein the light shielding material is a black inorganic pigment or a black organic pigment, the adhesive resin is 2-(methyl) acryloyloxyethyl phthalate, the small molecule monomer is styrene, acrylate or methacrylate, the photoinitiator is ethanone or 1-[9-ethyl-6 (2-methylbenzoyl)-9H-substituent carbazol-3-yl]-1-(oxo-acetyloxime), and the solvent is propylene glycol monomethyl ether acetate, cyclohexanone, 3-methoxy butyl acetate or 2-(2-butoxyethoxy)-Ethanol acetate.

4. The black matrix according to claim 3, wherein the black inorganic pigment is carbon black, chromium oxide, iron oxide, titanium oxide or graphite, and the black organic pigment is perylene black, cyanine black or aniline black.

5. The black matrix according to claim 1, wherein the mixture of resin compositions has the following composition: 5˜10 wt % of adhesive resin, 0˜1 wt % of photoinitiator, 0˜1 wt % of small molecule monomer, 70˜80 wt % of solvent, 5˜10 wt % of light shielding material, 1˜5 wt % of azo compound and 0˜0.5 wt % of additive.

6. A method for manufacturing a black matrix, comprising:
step 1, weighing 5˜10 wt % of adhesive resin, weighing 0˜1 wt % of photoinitiator, weighing 0˜1 wt % of small molecule monomer, weighing 70˜80 wt % of solvent, weighing 5˜10 wt % of light shielding material, weighing 1˜5 wt % of azo compound and weighing 0˜0.5 wt % of additive based on the total weight of a manufactured mixture of resin compositions, then mixing the weighed components for manufacturing the mixture of resin compositions, wherein the azo compound has the property of polarization; and
step 2, coating the mixture of resin compositions on a substrate and forming a black matrix having the property of polarization by soft baking, exposing, developing, and hard baking.

7. The method for manufacturing a black matrix according to claim 6, wherein in step 1, the azo compound has the formula of 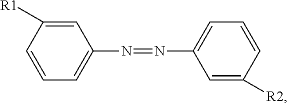
wherein R1 is amino, hydroxyl, alkoxy, ester, aminoacyl, amine-aldehyde, phenyl or alkyl, and R2 is acyl, aldehyde, carboxyl, amide, sulfonic acid, nitrile, nitro, haloform or quaternary amino.

8. The method for manufacturing a black matrix according to claim 6, wherein in step 1, the light shielding material is a black inorganic pigment or a black organic pigment, the adhesive resin is 2-(methyl) acryloyloxyethyl phthalate, the small molecule monomer is styrene, acrylate or methacrylate, the photoinitiator is ethanone or 1-[9-ethyl-6(2-methylbenzoyl)-9H-substituent carbazol-3-yl]-1-(oxo-acetyloxime), and the solvent is propylene glycol monomethyl ether acetate, cyclohexanone, 3-methoxy butyl acetate or 2-(2-butoxyethoxy)-Ethanol acetate.

9. The method for manufacturing a black matrix according to claim 8, wherein the black inorganic pigment is carbon black, chromium oxide, iron oxide, titanium oxide or graphite, and the black organic pigment is perylene black, cyanine black or aniline black.

10. A liquid crystal panel, comprising a CF substrate, a TFT substrate disposed opposite to the CF substrate and a liquid crystal layer filled between the CF substrate and the TFT substrate, wherein a black matrix and a color photoresist are disposed on the CF substrate, the black matrix being a black matrix according to any one of claims 1-5.

11-14. (canceled)
